(19) United States
(12) Patent Application Publication
(10) Pub. No.: US 2022/0077308 A1
(43) Pub. Date: Mar. 10, 2022

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Miwako SUZUKI, Kawasaki Kanagawa (JP)

(21) Appl. No.: 17/470,731

(22) Filed: Sep. 9, 2021

(30) Foreign Application Priority Data
Sep. 10, 2020 (JP) 2020-152178

(51) Int. Cl. H01L 29/78; H01L 29/10; H01L 29/06

(52) U.S. Cl. CPC H01L 29/7802; H01L 29/0607; H01L 29/1095

(57) ABSTRACT

A semiconductor device comprises a substrate of a first type, a drift layer of the first type, a plurality of base layers of a second type, a first electrode, an insulating layer, a second electrode, and a third electrode. The drift layer is formed on the substrate. The plurality of base layers is periodically formed extending in a direction in a surface of the drift layer. The first electrode is selectively formed extending in the direction in the surface of the base layers. The insulating layer is formed of an oxide film on the drift layer and on the base layer. The second electrode is formed extending in the direction with at least a part thereof overlapping with the first electrode via the oxide film. The third electrode is formed extending in the direction on the drift layer via the oxide film, between the second electrodes in the insulating layer.

### CROSS REFERENCE TO THE RELATED APPLICATIONS

This application is based upon and claims the benefit of priority from the prior Japanese Patent Application No. 2020-152178, filed on Sep. 10, 2020, the entire contents of which are incorporated herein by reference.

### FIELD

Embodiments of the present invention relate to a semiconductor device.

### BACKGROUND

A power MOSFET (Metal-Oxide-Semiconductor Field-Effect Transistor) is used for using a large amount of power in various devices. In the power device, the depletion layer is extended to secure the withstand voltage, and the depletion layer width is in a proportional relation with the drift layer concentration, so that the concentration of the drift layer needs to be made lower as the withstand voltage becomes higher. On the other hand, the on-resistance becomes higher as the drift concentration becomes lower, and therefore the withstand voltage and the on-resistance are in a trade-off relation. One of structures which improve the trade-off between the withstand voltage and the on-resistance in the power device is a super junction structure. In the super junction structure, a P type layer is formed in an N type drift layer, thereby enabling an increase in N type concentration and a decrease in on-resistance. The decrease in the on-resistance makes it possible to reduce the chip size and, as a result, decrease the capacitance, thereby forming an element high in switching speed.

However, the switching speed and the ringing at switching are in a trade-off relation. The ringing at the switching causes EMI (Electromagnetic Interference) noise or the like. Therefore, as the switching speed is made higher, the noise due to the ringing more often causes a problem. In recent years, products high in switching speed increase, and therefore an improvement of the ringing problem is expected.

### BRIEF DESCRIPTION OF THE DRAWINGS

FIG. 1 is a sectional view of a semiconductor device according to an embodiment;

FIG. 2 is an internal circuit diagram of the semiconductor device according to the embodiment;

FIG. 3 is a plan view of the semiconductor device in FIG. 1;

FIG. 4 is a planar sectional view of the semiconductor device in

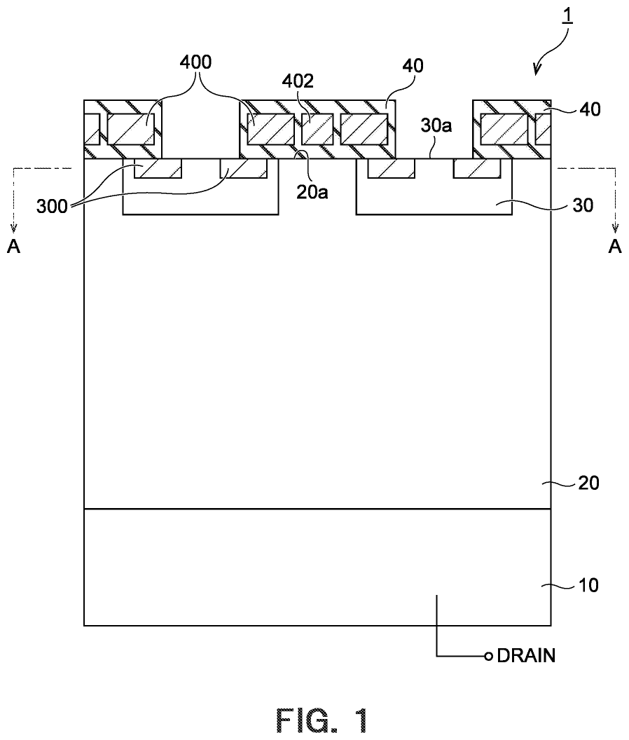

FIG. 1;

FIG. 5 is a sectional view of a semiconductor device according to an embodiment; and

FIG. 6 is a graph illustrating simulation results of a semiconductor device according to the embodiment.

### DETAILED DESCRIPTION

According to one embodiment, a semiconductor device comprises a substrate, a drift layer, a plurality of base layers, a first electrode, an insulating layer, a second electrode, and a third electrode. The substrate is formed of a first conductivity type. The drift layer is formed of the first conductivity type and formed on the substrate. The plurality of base layers are formed of a second conductivity type and are periodically formed extending in a predetermined direction in a predetermined surface of the drift layer. The first electrode is selectively formed extending in the predetermined direction in the predetermined surface of each of the base layers. The insulating layer is formed of an oxide film on the drift layer and selectively on the base layer. The second electrode is formed extending in the predetermined direction with at least a part thereof overlapping with the first electrode via the oxide film, in the insulating layer. The third electrode is formed extending in the predetermined direction on the drift layer via the oxide film, between the second electrodes in the insulating layer.

Hereinafter, embodiments will be explained referring to the drawings. Each of the embodiments in this disclosure can be used, for example, as a snubber circuit in a DMOS. The explanation is made with the type of the semiconductor in each region set, but the type is cited as an example. The n type and the p type may be inverted as long as an appropriate operation can be realized.

### First Embodiment

FIG. 1 is a sectional view schematically illustrating a semiconductor device according to a first embodiment. A semiconductor device 1 includes a substrate 10, a drift layer 20, a base layer 30, and an insulating layer 40.

The substrate 10 is formed of, for example, an n+ type silicon. The substrate 10 operates, for example, as a drain.

The drift layer 20 is, for example, an n type semiconductor layer formed on the substrate 10. Since current flows through the drift layer 20 in driving, the drift layer 20 may be formed with the n type concentration adjusted (for example, to an n− type) in a range suitable for use as a DMOS. The adjustment of the concentration makes it possible to decrease the on-resistance of the semiconductor device 1.

The base layer 30 is formed in the drift layer 20. The base layers 30 are periodically provided in shapes extending, for example, in a direction vertical to the drawing. The base layer 30 may be formed such that a predetermined surface 20a of the drift layer 20 and a predetermined surface 30a of the base layer 30 are almost flush with each other. Hereinafter, the predetermined surface 30a of the base layer 30 is described as the predetermined surface 20a without being discriminated from the predetermined surface 20a of the drift layer 20. The base layer 30 includes a source electrode 300.

The source electrode 300 is provided in the base layer 30 while extending in the same direction as the direction in which the base layer 30 extends. For example, two source electrodes 300 are provided in a state of separating from each other in the base layer 30 as illustrated in the drawing. In other words, in one base layer, two source electrodes 300 are formed while extending in the predetermined direction via the base layer 30 so as to share the base layer 30 and the predetermined surface 20a. The source electrode 300 may be formed, for example, of an n type or an n+ type semiconductor layer. Besides, as another example, the source electrode 300 may be formed containing a metal having an appropriate characteristic.

The insulating layer 40 is formed of an oxide film, for example, on the drift layer 20 and selectively on the base layer 30. As illustrated in FIG. 1, the insulating layer is formed in a manner to cover the drift layer 20 and cover a part of the base layer 30. The insulating layer 40 includes a gate electrode 400 and a field plate electrode (hereinafter, described as an FP electrode 402).

The gate electrode 400 is an electrode which applies a gate voltage.

By applying the drain voltage to the substrate 10, applying the source voltage to the base layer 30 and the source electrode 300, and applying the gate voltage to the gate electrode 400, the semiconductor device 1 flows current between the drain and the source. More specifically, by applying the above voltages, a channel is formed in the base layer 30 between the source electrode 300 and the gate electrode 400, and carriers move between the drain and the source via the channel, thereby flowing current. For example, by applying predetermined voltages to the drain and the source and applying a voltage exceeding a threshold to the gate in this state, the semiconductor device 1 can be used as a switch.

The FP electrode 402 is an electrode which is provided between the gate electrodes 400 provided in the insulating layer 40. The FP electrode 402 is electrically connected, for example, to the source electrode 300. Further, the FP electrode 402 desirably has some resistance.

By applying the source voltage to the FP electrode 402, a drain-source parasitic capacitance is formed between the drift layer 20 and the FP electrode 402 in the insulating layer 40. At the timing when current flows between the drain and the source, this capacitance and the resistance of the FP electrode 402 operate as the snubber circuit by RC connection.

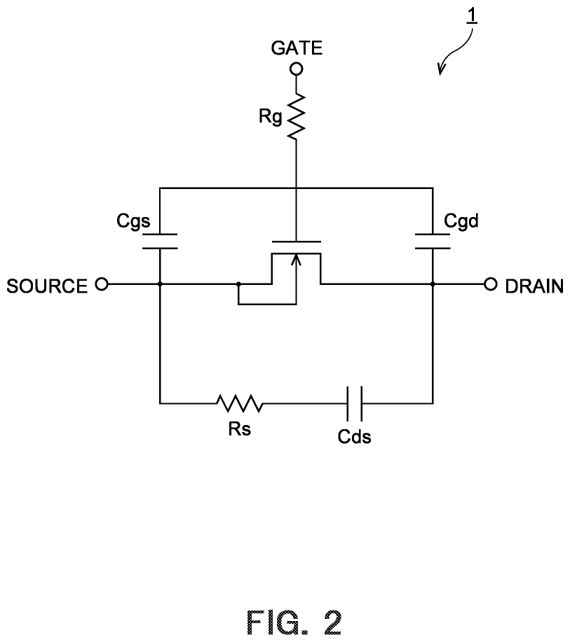

FIG. 2 illustrates the connection of the above semiconductor device 1 as a circuit diagram. The drain is connected to the substrate 10, the source is connected to the source electrode 300, and the gate is connected to the gate electrode 400.

A resistance Rg represents the resistance of the gate electrode 400, and Cgs and Cgd represent the gate-source parasitic capacitance and the gate-drain parasitic capacitance, respectively. The FP electrode 402 is represented by a resistance Rs and a capacitance Cds.

As explained above, the source voltage is applied to the FP electrode 402. The resistance Rs is the resistance of the FP electrode 402. The capacitance Cds is the capacitance formed by the drift layer 20 and the FP electrode 402 via an oxide film. Referring to the circuit diagram, it is found that the resistance Rs and the capacitance Cds are provided in parallel to the MOSFET operating as a switch. This shows that the FP electrode 402 operates as the snubber circuit.

For operating as the snubber circuit, the resistance Rs and the capacitance Cds may be appropriately set. This setting depends, for example, on parameters such as the size and material of the FP electrode 402, the distance between the FP electrode 402 and the drift layer 20, the area where they are in contact with each other via the oxide film, and so on.

As explained above, according to this embodiment, the gate electrode is provided corresponding to each of the source electrodes and the FP electrode is provided between the gate electrodes in the planar vertical MOSFET, thereby making it possible to form the snubber circuit. With the effect as the snubber circuit, it is possible to suppress the oscillation of the voltage due to the high performance of switching, in addition to the high withstand voltage and the low on-resistance which are advantages of the vertical MOSFET. In other words, the ringing at switching can be reduced. This structure can be made, for example, into the same configuration also in the DMOS or the like as in the simple vertical MOSFET illustrated in FIG. 1.

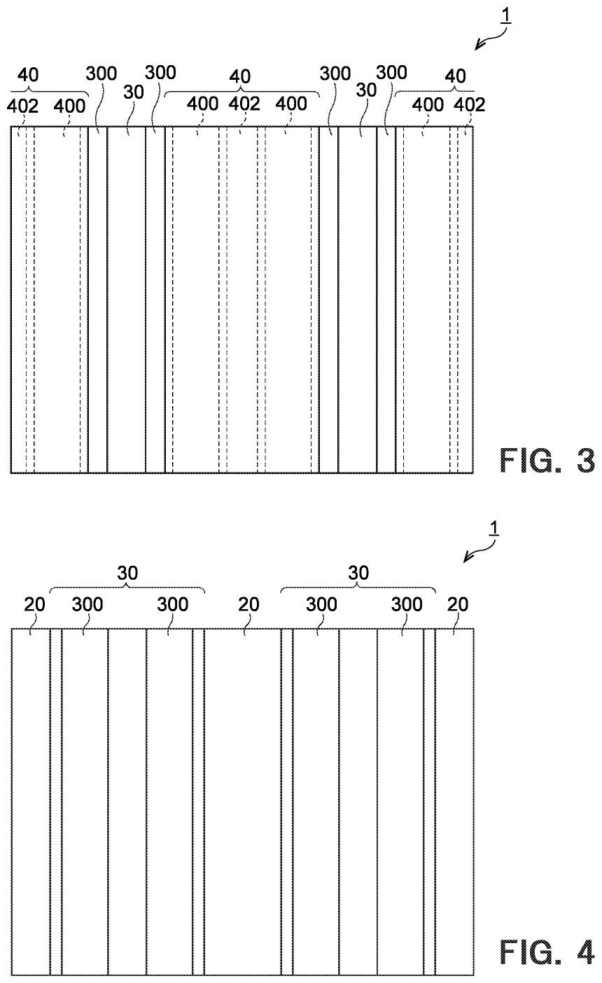

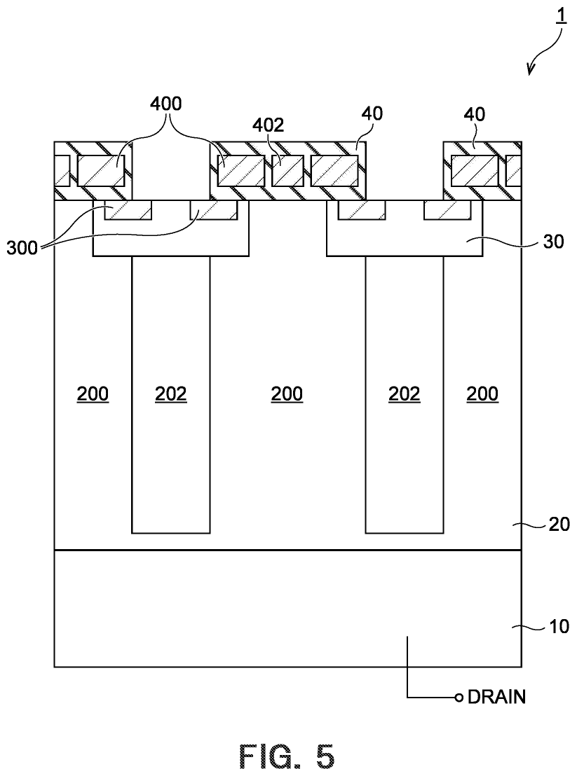

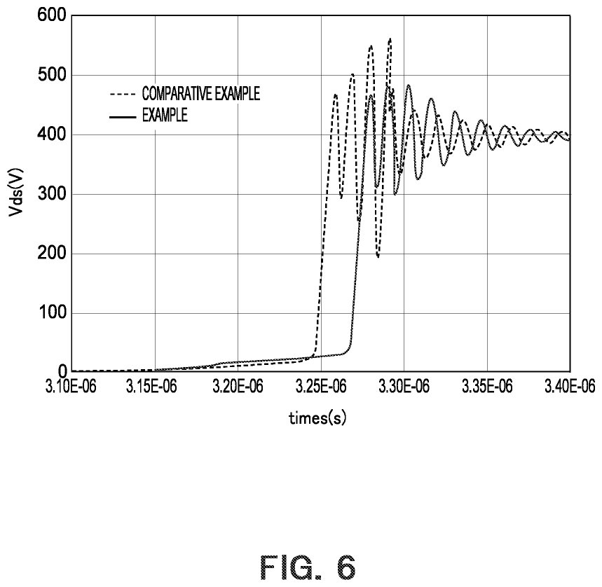

FIG. 3 is a plan view of the semiconductor device 1 according to this embodiment. FIG. 4 is an A-A sectional view of FIG. 1. The configuration in the plan view will be explained using the two drawings. Note that the semiconductor device 1 is merely partially illustrated. Though not illustrated as in FIG. 1, wiring is connected to each electrode so as to apply an appropriate voltage thereto.

First, as explained above, the semiconductor device 1 includes the drift layer 20 formed on the substrate 10, and the base layers 30 on the upper surface side of the drift layer 20. As illustrated in FIG. 4, the base layers 30 are periodically provided extending in a predetermined direction (an up-down direction in the drawing) in the predetermined surface of the drift layer 20. In the base layer 30, the source electrodes 300 are provided similarly extending in the predetermined direction. The source electrodes 300 are provided, for example, on both sides in one base layer 30. The source electrodes 300 are selectively provided extending in the predetermined direction in the predetermined surface of the base layer 30.

As illustrated in FIG. 3, the insulating layers 40 are provided on the drift layer 20 and selectively on the base layers, on the upper side (on the vertically front side with respect to the drawing). In the insulating layer 40, the gate electrodes 400 and the FP electrode 402 are provided extending in the predetermined direction. The gate electrodes 400 are provided on both sides in the insulating layer 40 via the oxide film such that a part of the gate electrode 400 overlaps with the position where the source electrode 300 is arranged and a part of the gate electrode 400 overlaps with the base layer 30 and the drift layer 20. The FP electrode 402 is provided between the gate electrodes 400 provided on both sides in the insulating layer 40 with the oxide film interposed between the FP electrode 402 and the gate electrodes 400.

As illustrated in FIG. 1, FIG. 3, and FIG. 4, the semiconductor device 1 according to this embodiment forms a vertical MOSFET.

### Second Embodiment

The semiconductor device 1 according to the above embodiment has a form having no pillar, but not limited to this, the semiconductor device 1 may have a pillar. In other words, the semiconductor device 1 may be a super-junction MOSFET.

FIG. 5 is a sectional view schematically illustrating a semiconductor device according to this embodiment. The semiconductor device 1 has the drift layer 20 composed of pillars in addition to the configuration of the above-explained semiconductor device 1.

The drift layer 20 includes, for example, n type first pillars 200 and p type second pillars 202.

The first pillar 200 is a pillar formed as a drift region, and the current between the drain and the source flows through the first pillar 200.

The second pillar 202 is a pillar formed on the lower side of the base layer 30, and controls the spread of a depletion layer in the drift region to suppress the occurrence of breakdown, thereby enhancing the withstand voltage property.

Even this super-junction MOSFET may be configured to have the FP electrode 402 in the gate region. The operation and the effect by the FP electrode 402 are the same as those in the above first embodiment

FIG. 6 is a graph illustrating the simulation results of a drain-source voltage Vds in a case where the FP electrode 402 is not provided, namely, the resistance of the FP electrode 402 is set to 0Ω (comparative example) and a case where the resistance value of the FP electrode 402 is set to 1Ω (example) in this embodiment. A solid line indicates the voltage according to this embodiment, and a dotted line indicates the voltage of the comparative example.

As illustrated in FIG. 6, it is found that the semiconductor device 1 of this embodiment suppresses the oscillation of voltage as compared with the comparative example.

As explained above, according to this embodiment, the FP electrode is formed in the planar gate region in the super-junction MOSFET, thereby enabling suppression of the oscillation of voltage depending on the high-performance switching property. In short, the ringing at switching can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate of a first conductivity type;
a drift layer of the first conductivity type formed on the substrate;
a plurality of base layers of a second conductivity type periodically formed extending in a predetermined direction in a predetermined surface of the drift layer;
a first electrode selectively formed extending in the predetermined direction in the predetermined surface of each of the base layers;
an insulating layer formed of an oxide film on the drift layer and selectively on the base layer;
a second electrode formed extending in the predetermined direction with at least a part thereof overlapping with the first electrode via the oxide film, in the insulating layer; and
a third electrode formed extending in the predetermined direction on the drift layer via the oxide film, between the second electrodes in the insulating layer.

2. The semiconductor device according to claim 1, wherein:
the drift layer includes:
a first pillar of the first conductivity type; and
a second pillar of the second conductivity type; and
the base layer is formed on the second pillar.

3. The semiconductor device according to claim 1, wherein
the third electrode is connected to have a same potential as a potential of the first electrode.

4. The semiconductor device according to claim 1, wherein:
the first conductivity type is an n type; and
the second conductivity type is a p type.

5. The semiconductor device according to claim 1, wherein
the first electrode is a semiconductor layer of the first conductivity type.

6. The semiconductor circuitry according to claim 1, wherein:
the first electrode is a source electrode;
the second electrode is a gate electrode; and
the third electrode is a field plate electrode.
